(19) United States
(12) Patent Application Publication
(10) Pub. No.: US 2025/0141152 A1
(43) Pub. Date: May 1, 2025

(54) SOCKET ASSEMBLY AND ELECTRICAL CONNECTOR COMPRISING THE SAME

(71) Applicant: Tyco Electronics (Shanghai) Co., Ltd., Shanghai (CN)

(72) Inventors: Yongfeng (Richard) Ma, Shanghai (CN); WenYu (Vindy) Liu, Shanghai (CN); Guangming (Suny) Zhao, Shanghai (CN)

(73) Assignee: Tyco Electronics (Shanghai) Co., Ltd., Shanghai (CN)

(21) Appl. No.: 18/930,214

(22) Filed: Oct. 29, 2024

(30) Foreign Application Priority Data
Oct. 30, 2023 (CN) 202311423038.5

(51) Int. Cl. H01R 13/533; H05K 7/20

(52) U.S. Cl. CPC H01R 13/533; H05K 7/2049; H05K 7/20409

(57) ABSTRACT

A socket assembly comprises a housing and a first heat conducting member. The housing defines a first channel adapted to accommodate a first module inserted therein. The first heat conducting member is installed on the housing such that a bottom surface of the first heat conducting member is adapted to be in contact with the first module to dissipate the heat generated by the first module. The first heat conducting member includes a guiding feature protruding from the bottom surface and engaging with a guiding groove formed in the first module for guiding the first module to be inserted into the first channel. The guiding feature is adapted to be stationary relative to the bottom surface when the first module is guided to be inserted into the first channel and abutted against the bottom surface so as to move the bottom surface relative to the housing.

### CROSS-REFERENCE TO RELATED APPLICATION

This application claims the priority of Chinese Patent Application No. CN 202311423038.5 filed on Oct. 30, 2023, the whole disclosure of which is incorporated herein by reference.

### FIELD OF THE DISCLOSURE

The present disclosure relates to a socket assembly and an electrical connector comprising the same.

### BACKGROUND OF THE INVENTION

A connector is a device used to connect two active devices to transmit current or signals. A connector may simplify an assembly process of electronic product and also simplify a mass production process of the electronic products. A connector is easy to repair, and if an electronic component fails, the failed component may be quickly replaced with a connector installed. With an advancement of technology, the electronic product provided with a connector may use updated electronic components, replacing old electronic components with new and better performing ones for easy upgrading. A connector may enhance a flexibility of product design when designing and integrating a new product, as well as when composing a system with electronic components. Therefore, connectors are widely used in fields such as transportation, healthcare, aerospace, military, and home appliances.

The basic performances of a connector may be divided into three categories: mechanical performance, electrical performance, and environmental performance. Insertion and extraction force and mechanical life are important mechanical performances. The insertion and extraction force and mechanical life of a connector are related to a structure of a contact (a magnitude of a positive pressure), a quality of a coating on a contact area (sliding friction coefficient), and an accuracy of a size of an arrangement of the contacts (alignment precision).

Main electrical performances of a connector comprise a contact resistance, an insulation resistance, and a dielectric strength. Among them, a high-quality electrical connector should have a low and stable contact resistance, which ranges from a few milliohms to tens of milliohms. An insulation resistance is an index that measures the insulation performance between the contacts of an electrical connector and between the contacts and a housing of the connector. An order of magnitude of the insulation resistance ranges from hundreds of megaohms to thousands of megaohms. Dielectric strength is an ability of a connector to withstand a rated test voltage between the contacts of the connector or between the contacts and the housing.

Environmental performance comprises a temperature resistance, a humidity resistance, a salt spray resistance, a vibration and an impact resistance, etc.

The development of connector technology presents the following characteristics: high-speed and digitalization of signal transmission, integration of various signal transmissions, miniaturization of product volume, low cost of products, modular combination, convenience of insertion and extraction, and so on.

In an existing electrical connector that uses a heat conducting member for heat dissipation, a guiding mechanism that guides an electronic module to be inserted into the electrical connector is prone to deform due to collision with the electronic module. This situation is particularly severe when a large external force is applied to insert the electronic module into the electrical connector. Therefore, it is urgent to provide a reliable guiding mechanism to improve an insertion and extraction performance of the electrical connector.

### SUMMARY OF THE INVENTION

According to an embodiment of the present disclosure, a socket assembly comprises a housing and a first heat conducting member. The housing defines a first channel adapted to accommodate a first module inserted therein. The first heat conducting member is installed on the housing such that a bottom surface of the first heat conducting member is in contact with the first module to dissipate the heat generated by the first module. The first heat conducting member includes a guiding feature protruding from the bottom surface and engaging with a guiding groove formed in the first module for guiding the first module to be inserted into the first channel. The guiding feature is adapted to be stationary relative to the bottom surface when the first module is guided to be inserted into the first channel and abutted against the bottom surface so as to move the bottom surface relative to the housing.

### BRIEF DESCRIPTION OF DRAWINGS

The accompanying drawings incorporated therein and forming a part of the specification illustrate the present disclosure and, and together with the description, further serve to explain the principles of the disclosure and to enable those skilled in the relevant art to manufacture and use the embodiments described herein.

FIG. 1 is a perspective view of a socket assembly with a first module inserted therein according to an embodiment of the disclosure;

FIG. 2 is a perspective view of an individual first module shown in FIG. 1;

FIG. 3 is a perspective view of an individual socket assembly shown in FIG. 1;

FIG. 4 is a bottom view of an individual first heat conducting member shown in FIG. 1;

FIG. 5 is a bottom view of a portion of the first heat conducting member shown in FIG. 4, showing a guiding plate;

FIG. 6 is a perspective view of the socket assembly shown in FIG. 3 with one sidewall removed, showing two channels and two heat conducting members respectively accommodated in the two channels;

FIG. 7 is a side view of an individual guiding feature shown in FIG. 5;

FIG. 8 is a side view of an individual first upper plate and an individual first lower plate shown in FIG. 5;

FIG. 9 is a side view of an individual second upper plate and an individual second lower plate shown in FIG. 5;

FIG. 10 is a side view of FIG. 5; and

FIG. 11 is a perspective view of an individual elastic member shown in FIG. 5.

The features disclosed in this disclosure will become more apparent in the following detailed description in conjunction with the accompanying drawings, where similar reference numerals always identify the corresponding components. In the accompanying drawings, similar reference numerals typically represent identical, functionally similar, and/or structurally similar components. Unless otherwise stated, the drawings provided throughout the entire disclosure should not be construed as drawings drawn to scale.

### DETAILED DESCRIPTION

In order to make the purpose, technical scheme and advantages of the present disclosure more clear, the following is a detailed explanation of the present disclosure, combined with specific embodiments and referring to the attached drawings.

However, it should be understood that these descriptions are only illustrative and not intended to limit the scope of the present disclosure. In the following detailed description, for case of interpretation, many specific details are elaborated to provide a comprehensive understanding of the embodiments of the present disclosure. However, it is evident that one or more embodiments may also be implemented without these specific details. In addition, in the following explanation, the description of the well-known technology is omitted to avoid unnecessary confusion with the concept of the present disclosure.

The terms used here are only for describing specific embodiments and are not intended to limit the present disclosure. The term “comprising” used here indicates the existence of features, steps and operations, but does not exclude the existence or addition of one or more other features.

In the case of using expressions such as “at least one of A, B, and C, etc.” or the like, it should generally be interpreted in accordance with the meaning of the expressions that those skilled in the art usually understand (for example, “a system with at least one of A, B, and C” should comprise but not be limited to a system with only A, a system with only B, a system with only C, a system with A and B, a system with A and C, a system with B and C, and/or a system with A, B, C, etc.).

All terms used here (comprising technical and scientific terms) have the meanings commonly understood by those skilled in the art, unless otherwise defined. It should be noted that the terms used here should be interpreted as having a meaning consistent with the context of this specification, and should not be interpreted in an idealized or overly rigid manner.

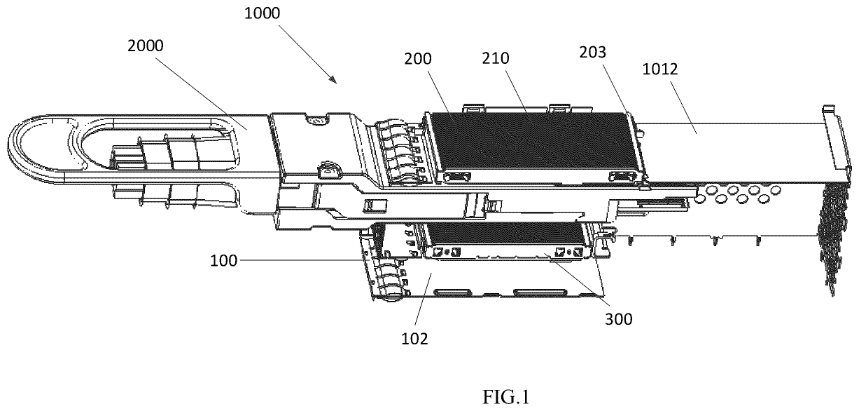

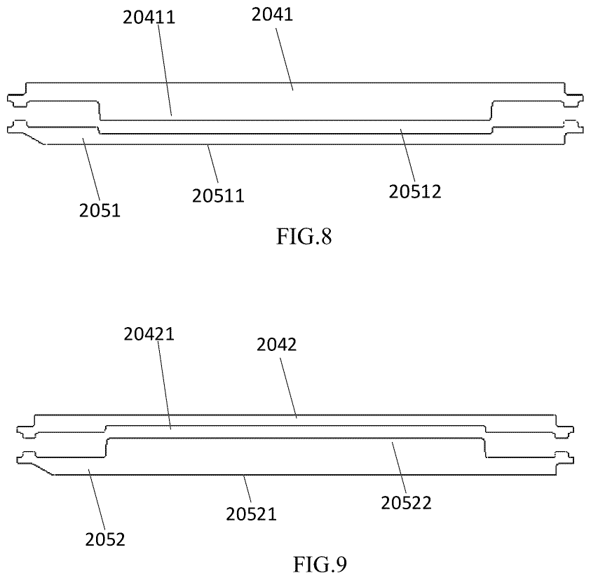

Referring to FIGS. 1-11, the present disclosure discloses a socket assembly 1000 and a connector (not shown in the figures) comprising the socket assembly 1000 and a circuit board (not shown in the figures) installed with the socket assembly 1000.

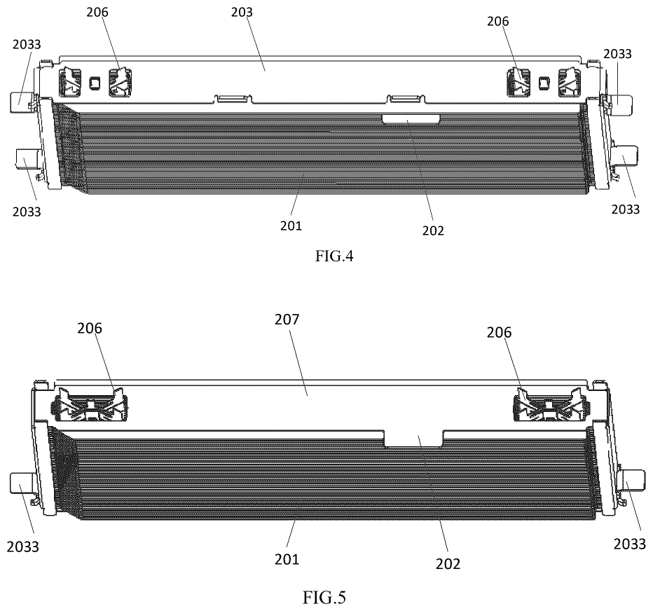

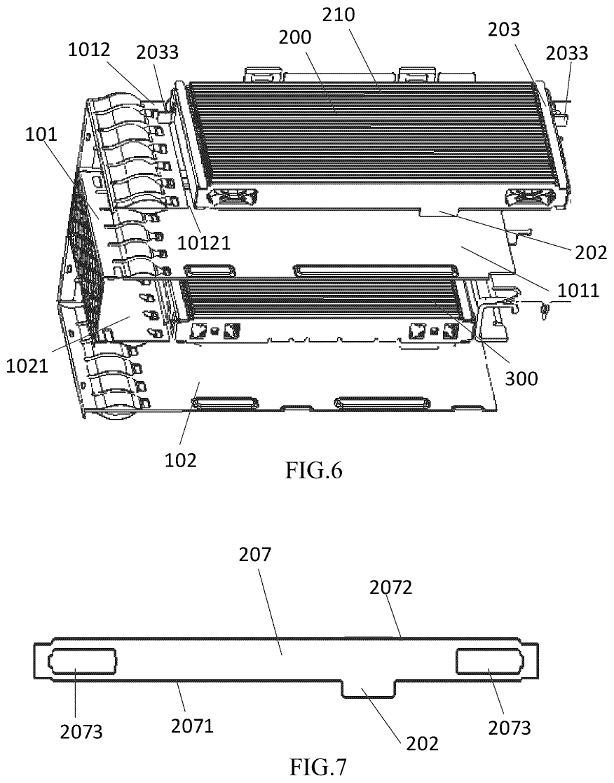

The socket assembly 1000 comprises a housing 100 and a first heat conducting member 200. The housing 100 comprises a first channel 101 for accommodating a first module 2000 inserted therein. The first module 2000 is an electronic component capable of conducting current and generating heat. The first heat conducting member 200, also known as a “thermal bridge”, is installed on a top wall 1012 of the first channel 101 of the housing 100 in a manner that the first heat conducting member 200 is at least partially accommodated in the first channel 101. The top wall 1012 is provided with an opening 10121 (see FIG. 6) configured to accommodate the first heat conducting member 200, so that a bottom surface 201 of the first heat conducting member 200 may enter the first channel 101 through the opening 10121, so as to be in contact with the first module 2000 to dissipate the heat generated by the first module 2000. The first heat conducting member 200 comprises a guiding feature 202 protruding from the bottom surface 201. The guiding feature 202 is configured to be matched with a guiding groove 2001 in terms of shape formed in the first module 2000 so as to guide the first module 2000 to be inserted into the first channel 101. Although in the embodiment of the disclosure, the guiding feature 202 is configured as a form of a tab (see FIGS. 4 to 7), those skilled in the art should understand that this is not restrictive, and the guiding feature 202 may be configured as any form suitable for guiding the first module 2000 to be inserted into the first channel 101.

When the first module 2000 is guided to be inserted into the first channel 101 and abutted against the bottom surface 201 so as to move the bottom surface 201 relative to the housing 100, the guiding feature 202 is configured to not move with the bottom surface 201 but remain fixed or static relative to the housing 100, so that the guiding feature 202 will not displace or deform when there is a large force between the guiding feature 202 and the guiding groove 2001 (for example, when the first module 2000 is inserted into the first channel 101 with the large force), resulting in a high reliability and improving an insertion and extraction performance of the connector comprising the socket assembly 1000.

The first heat conducting member 200 comprises: a frame 203, a plurality of upper plates 2041, 2042, a plurality of lower plates 2051, 2052, an elastic member 206, and a guiding plate 207.

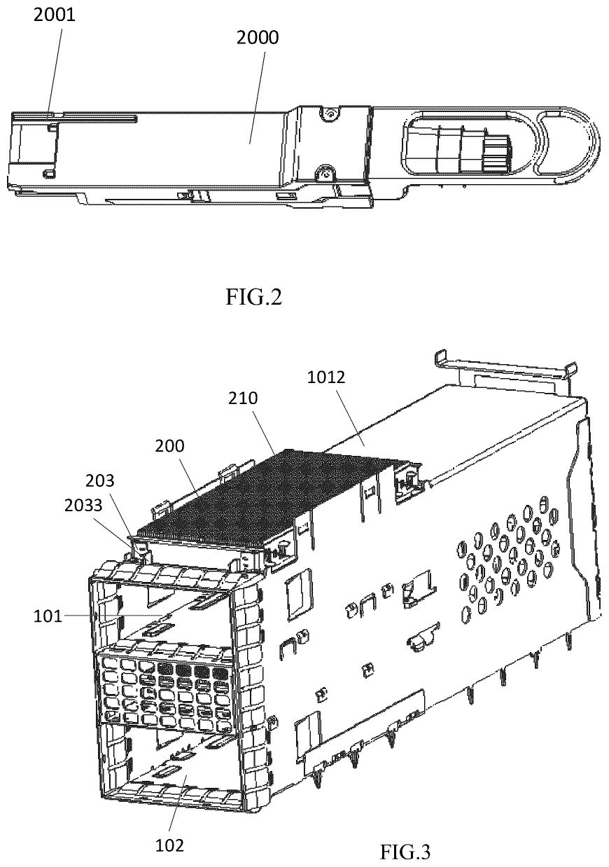

The frame 203 is provided along a circumference of the first heat conducting member 200, and is provided with mounting members 2033 respectively installed on two opposite ends 2031, 2032 of the frame 203 in an extension direction of the first channel 101 (see FIGS. 3 to 6). The mounting members 2033 are configured to abut against the top wall 1012 (see FIG. 6) so as to install the frame 203 onto the housing 100. A plurality of upper plates 2041, 2042 are arranged in the frame 203 side by side, respectively, and a plurality of lower plates 2051, 2052 are arranged in the frame 203 side by side, respectively. Each of the plurality of lower plates 2051, 2052 is aligned and at least partially matched with each of the plurality of upper plates 2041, 2042 in terms of shape, and lower ends 20511, 20521 of each of the lower plate 2051, 2052 are aligned with each other so as to form the bottom surface 201 (see FIGS. 4 and 5).

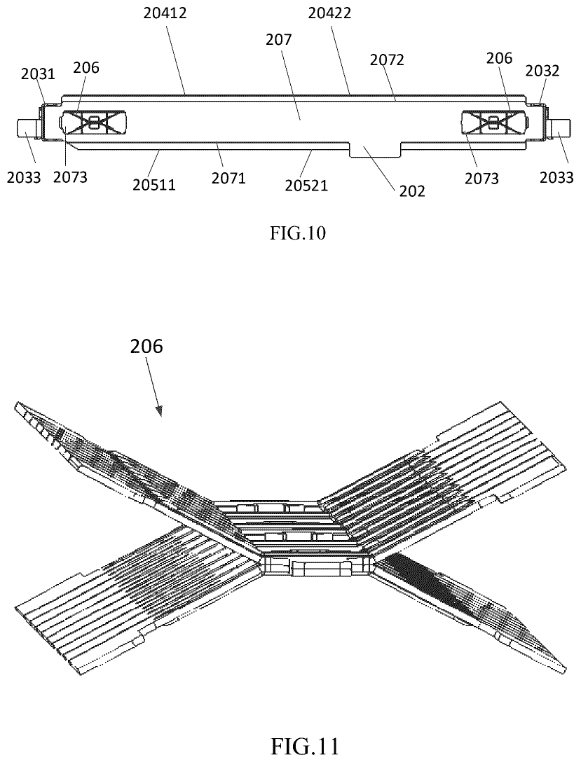

An elastic member 206 (see FIG. 11) with an x-shaped cross section is arranged between each said upper plate 2041, 2042 and each said lower plate 2051, 2052 aligned with each other (see FIGS. 6 and 10) so as to apply a bias pressure to each said upper plate 2041, 2042 and each said lower plate 2051, 2052 aligned with each other after the bottom surface 201 is moved, so as to press the bottom surface 201 against the first module 2000. The arrangement of the first heat conducting member 200 makes it compressible, and the following will provide a detailed description of this arrangement. The guiding plate 207 is provided with the guiding feature 202 and is configured to be parallel to the plurality of upper plates 2041, 2042 and the plurality of lower plates 2051, 2052.

The guiding plate 207 is positioned between two adjacent upper plates 2041, 2042, so that it does not abut against a side wall of the frame 203 so as to keep away from a side wall of the first channel 101, facilitating guiding the first module 2000 to be inserted into the first channel 101. A lower end 2071 of the guiding plate 207 is higher than the lower ends 20511, 20521 of each of the lower plates 2051, 2052 (see FIG. 10), which makes the guiding feature 202 not move upwards with the bottom surface 201 when the first module 2000 is inserted into the first channel 101 and abutted against the bottom surface 201 to move (i.e., push) the bottom surface 201 upwards relative to the housing 100. Upper ends 20412, 20422 of the plurality of upper plates 2041, 2042 are aligned with each other so as to define a top surface 210 (see FIGS. 1, 3, and 6). The lower end 2071 of the guiding plate 207 defines a final position where the bottom surface 201 stops moving when the first module 2000 is abutted against the bottom surface 201 so as to move the bottom surface 201 upwards. An upper end 2072 of the guiding plate 207 is lower than the upper ends 20412, 20422 of each of the upper plates 2041, 2042 (see FIG. 10) so as to define a final position where the top surface 210 stops moving when a heat sink (not shown in the figures) is abutted against the top surface 210 of the first heat conducting member 200 so as to move (i.e., push) the top surface 210 downwards. That is, the bottom surface 201 and the top surface 210 of the first heat conducting member 200 may be moved, making the first heat conducting member 200 compressible, which enhances a thermal contact of the first heat conducting member 200 with the heat sink and the first module 2000, and is conducive to improving an efficiency of transferring heat from the first module 2000 to the heat sink via the first heat conducting member 200.

The guiding plate 207 is provided with a hole 2073 through which the elastic member 206 is allowed to extend (see FIGS. 7 and 10) and which is sized to not compress the elastic member 206 extending therethrough so as to avoid any elastic deformation of the elastic member 206. In this way, the clastic deformation of the elastic member 206 is entirely caused by the relative positions between the upper plates 2041, 2042 and the lower plates 2051, 2052.

The plurality of upper plates 2041, 2042 comprise a first upper plate 2041 and a second upper plate 2042 arranged alternately with each other. The plurality of lower plates 2051, 2052 comprise a first lower plate 2051 and a second lower plate 2052 arranged alternately with each other. One first upper plate 2041 is aligned with one first lower plate 2051, and one second upper plate 2042 is aligned with one second lower plate 2052. The first upper plate 2041 is provided with a first protrusion 20411, and the first lower plate 2051 is provided with a first depression 20512 configured to be matched with the first protrusion 20411 in terms of shape. The second upper plate 2042 is provided with a second depression 20421, and the second lower plate 2052 is provided with a second protrusion 20522 configured to be matched with the second depression 20421 in terms of shape. The elastic member 206 is configured to pass between the upper plates 2041, 2042, and the lower plates 2051, 2052 on at least one side of the first protrusion 20411 and/or the second protrusion 20522.

The plurality of upper plates 2041, 2042, and the plurality of lower plates 2051, 2052 are configured such that the first protrusion 20411 and the first depression 20512 are separated from each other and the second protrusion 20522 and the second depression 20421 are separated from each other without the bottom surface 201 being moved. The first protrusion 20411 and the second protrusion 20522 adjacent to each other are configured to overlap with each other without the bottom surface 201 being moved, so that the first upper plate 2041 and the second lower plate 2052 adjacent to each other are always in thermal communication with each other. Therefore, regardless of whether the first heat conducting member 200 is compressed or not, all of the upper plates 2041, 2042 and lower plates 2051, 2052 in the first heat conducting member 200 are always in thermal communication with each other.

Two opposite ends of the guiding plate 207 are fixedly abutted against the two opposite ends 2031, 2032 of the frame 203 respectively, in order to be limited by the two ends 2031, 2032 of the frame 203 (i.e., a gap between the two opposite ends of the guiding plate 207 and the two opposite ends 2031, 2032 of the frame 203 is enough small, even zero), so that the guiding plate 207 remains fixed and does not move with the top surface 210 and bottom surface 201, further reinforcing the guiding feature 202, improving the reliability of the guiding feature 202 and the insertion and extraction performance of the connector comprising the socket assembly 1000.

Referring to FIGS. 1, 3, and 6, the housing 100 further comprises a second channel 102 and a second heat conducting member 300. The second channel 102 configured to be identical to the first channel 101 is configured to accommodate a second module inserted therein (not shown in the figures), to be separated from the first channel 101 and located below the first channel 101. The second heat conducting member 300 is configured to be identical to the first heat conducting member 200, and to be installed on the housing 100 in a manner that it is at least partially accommodated in the second channel 102, so that a bottom surface of the second heat conducting member 300 is in contact with the second module to dissipate the heat generated by the second module.

Referring to FIG. 6, a top wall 1021 of the second channel 102 is separated from a bottom wall 1011 of the first channel 101 so as to accommodate a portion of the second heat conducting member 300 exposed out of the second channel 102 and a heat sink (not shown in the figures) abutted against a top of the portion of the second heat conducting member 300.

At this point, a detailed description of the embodiments of the present disclosure has been provided in conjunction with the accompanying drawings. It should be noted that the implementation not shown or described in the accompanying drawings or the text of the specification are all forms known to the person skilled in the art that the present disclosure pertains to and have not been explained in detail. In addition, the above definitions of each of the components are not limited to the various specific structures, shapes, or methods mentioned in the embodiments, which may be easily modified or replaced by the person skilled in the art.

It should also be noted that in specific embodiments of the present disclosure, unless otherwise expressly stated, the numerical parameters in this specification and the attached claims are approximate values that may be changed based on the desired characteristics obtained by the content of the present disclosure. Specifically, all numbers used in the specification and claims to represent the dimensions, range conditions, etc. of the composition should be understood as being modified by the term “approximately” in all cases. In general, the meaning of the expression refers to an inclusion of a specific number of ±10% changes in some embodiments, ±5% changes in some embodiments, ±1% changes in some embodiments, and ±0.5% changes in some embodiments.

The person skilled in the art may understand that the features recorded in various embodiments and/or claims of the present disclosure may be combined or incorporated in a plurality of ways, even if such combinations or incorporations are not explicitly recorded in the present disclosure. Specifically, without departing from the spirit and teachings of the present disclosure, the features recorded in various embodiments and/or claims of the present disclosure may be combined and/or incorporated in a plurality of ways. All these combinations and/or incorporations fall within the scope of the present disclosure.

The specific embodiments described above provide further detailed explanations of the purpose, technical scheme, and beneficial effects of the present disclosure. It should be understood that the above explanations are only specific embodiments of the present disclosure and are not intended to limit the present disclosure. Any modifications, equivalent replacements, improvements, etc. made within the spirit and principles of the present disclosure should be comprised in the protection scope of the present disclosure.

1. A socket assembly comprising:
a housing defining a first channel adapted to accommodate a first module inserted therein; and
a first heat conducting member installed on the housing in a manner that it is at least partially accommodated in the first channel such that a bottom surface of the first heat conducting member is adapted to be in contact with the first module to dissipate the heat generated by the first module, the first heat conducting member including a guiding feature protruding from the bottom surface and engaging with a guiding groove formed in the first module for guiding the first module to be inserted into the first channel, the guiding feature is adapted to be stationary relative to the bottom surface when the first module is guided to be inserted into the first channel and abutted against the bottom surface so as to move the bottom surface relative to the housing.

2. The socket assembly according to claim 1, wherein the first heat conducting member comprises:
a frame adapted to be installed onto the housing;
a plurality of upper plates arranged in the frame side by side;
a plurality of lower plates arranged in the frame side by side, each of which is aligned with and at least partially matched with each of the upper plates and having lower ends aligned with each other so as to form the bottom surface;
an elastic member arranged between each said upper plate and each said lower plate aligned with each other and applying a bias pressure to each said upper plate and each said lower plate aligned with each other after the bottom surface is moved, in order to press the bottom surface against the first module; and
a guiding plate provided with the guiding feature and arranged parallel to the plurality of upper and lower plates.

3. The socket assembly according to claim 2, wherein the guiding plate is positioned between two adjacent ones of the upper plates, a lower end of the guiding plate is higher than the lower end of each of the lower plates, and an upper end of the guiding plate is lower than an upper end of each of the upper plates.

4. The socket assembly according to claim 3, wherein the guiding plate includes a hole through which the elastic member extends and which is sized to prevent any elastic deformation of the elastic member extending therethrough.

5. The socket assembly according to claim 4, wherein:
the plurality of upper plates comprise first and second upper plates arranged alternately with each other;
the plurality of lower plates comprise first and second lower plates arranged alternately with each other; and
the first upper plate is aligned with the first lower plate, and the second upper plate is aligned with the second lower plate.

6. The socket assembly according to claim 5, wherein the first upper plate is provided with a first protrusion, and the first lower plate is provided with a first depression adapted to be complementary with the first protrusion.

7. The socket assembly according to claim 6, wherein the second upper plate is provided with a second depression, and the second lower plate is provided with a second protrusion adapted to be complementary to the second depression, the elastic member is adapted to pass between the upper plate and the lower plate on at least one side of the first protrusion and/or the second protrusion.

8. The socket assembly according to claim 7, wherein the plurality of upper plates and the plurality of lower plates are adapted such that the first protrusion and the first depression are separated from each other and the second protrusion and the second depression are separated from each other without the bottom surface being moved.

9. The socket assembly according to claim 8, wherein the first protrusion and the second protrusion adjacent to each other are configured to overlap with each other without the bottom surface being moved.

10. The socket assembly according to claim 9, wherein the elastic member has an x-shaped cross section.

11. The socket assembly according to claim 10, wherein two opposite ends of the guiding plate are fixedly abutted against two opposite ends of the frame, respectively.

12. The socket assembly according to claim 1, wherein the housing further comprises a second channel adapted to accommodate a second module inserted therein and to be separated from the first channel.

13. The socket assembly according to claim 12, wherein a second heat conducting member identical to the first heat conducting member is installed on the housing in a manner that it is at least partially accommodated in the second channel so that a bottom surface of the second heat conducting member is in contact with the second module so as to dissipate the heat from the second module.

14. The socket assembly according to claim 13, wherein a top wall of the second channel is separated from a bottom wall of the first channel to accommodate a portion of the second heat conducting member exposed out of the second channel.

15. A socket assembly comprising:
a first module defining a guiding groove;
a housing defining a first channel receiving the first module therein; and
a first heat conducting member installed on the housing and at least partially accommodated in the first channel, a bottom surface of the first heat conducting member in contact with the first module to dissipate the heat generated by the first module, the first heat conducting member including a guiding feature protruding from the bottom surface and engaging with the guiding groove of the first module for guiding the first module to be inserted into the first channel, the guiding feature is stationary relative to the bottom surface as the first module is guided into the first channel and abutted against the bottom surface so as to move the bottom surface relative to the housing.

16. The socket assembly according to claim 15, wherein the first heat conducting member comprises:
a frame installed onto the housing;
a plurality of upper plates arranged in the frame;
a plurality of lower plates arranged in the, each of which is aligned with and at least partially matched with each of the upper plates and having lower ends aligned with each other so as to form the bottom surface.

17. The socket assembly according to claim 16, wherein the first heat conducting member further comprises an elastic member arranged between each said upper plate and each said lower plate aligned with each other and applying a bias pressure to each said upper plate and each said lower plate aligned with each other after the bottom surface is moved, in order to press the bottom surface against the first module.

18. The socket assembly according to claim 17, wherein the first heat conducting member further comprises a guiding plate provided with the guiding feature and arranged parallel to the plurality of upper and lower plates.
